(19) United States
(12) Patent Application Publication
(10) Pub. No.: US 2013/0020913 A1
(43) Pub. Date: Jan. 24, 2013

(54) ELECTRONIC COMPONENT AND METHOD FOR MANUFACTURING ELECTRONIC COMPONENT

(71) Applicants: Yukihiko SHIRAKAWA, Tokyo (JP); Tatsuo INAGAKI, Tokyo (JP); Shintaro KON, Nikaho-shi (JP); Hiromitsu NOGIWA, Tokyo (JP)

(72) Inventors: Yukihiko SHIRAKAWA, Tokyo (JP); Tatsuo INAGAKI, Tokyo (JP); Shintaro KON, Nikaho-shi (JP); Hiromitsu NOGIWA, Tokyo (JP)

(73) Assignee: TDK CORPORATION, Tokyo (JP)

(21) Appl. No.: 13/546,497

(22) Filed: Jul. 11, 2012

(30) Foreign Application Priority Data
Jul. 20, 2011 (JP) 2011-159030

(51) Int. Cl. H01L 41/047; H01R 43/16; H01G 4/005; H01G 4/008; H01C 7/10; H01F 5/00

(52) U.S. Cl. 310/364; 310/365; 338/22 R; 336/200; 361/303; 361/305; 29/874

(57) ABSTRACT

An electronic component has an element body, an external electrode, and an insulating material. The element body has a pair of end faces opposed to each other, a pair of principal faces extending so as to connect the pair of end faces and opposed to each other, and a pair of side faces extending so as to connect the pair of principal faces and opposed to each other. The external electrode is formed on the end face side of the element body and covers a partial region of the principal face and/or a partial region of the side face adjacent to the end face. The insulating material covers a surface of the element body except for one face which is the principal face or the side face and at least a part of which is covered by the external electrode, and the external electrode formed on the surface.

### BACKGROUND OF THE INVENTION

1. Field of the Invention

The present invention relates to an electronic component and a method for manufacturing the electronic component.

2. Related Background Art

The following method is used as a method for manufacturing a surface-mount component (e.g., a multilayer ceramic capacitor or the like) (for example, reference is made to Japanese Patent Application Laid-open No. 2006-13315). An element body is formed by alternately stacking green sheets and internal electrode materials and firing a laminate body thereof. End faces of the element body are dipped into an electroconductive paste so as to attach the electroconductive paste to the element body and then the attached electroconductive paste is dried to form paste layers. The paste layers are sintered on the element body and thereafter plated layers are formed thereon in order to improve solderability. These processes provide the element body with the external electrodes formed thereon.

In the above-described conventional manufacturing method, the external electrodes are formed spreading over the two end faces of the element body and partial regions of the principal faces and the side faces adjacent to the end faces. The external electrodes have a five-face electrode structure (a structure formed over five surfaces of the element body).

When an electronic component 101 is mounted on a substrate SS with wiring patterns WP by soldering, as shown in FIGS. 12 to 15, solder also flows around onto external electrodes 103 formed on side faces of the electronic component 101 to form solder fillets SF on the side faces of the external electrodes 103 as well. When a plurality of electronic components 101 are mounted in parallel or series arrangement, a solder bridge can be formed between side face portions or between an end face portion and a side face portion of adjacent electronic components 101. For this reason, a short-circuit problem is likely to arise between electronic components 101 and it was difficult to realize close adjacent high-density mounting with reduced spacing between electronic components 101. If an electronic component 101 is mounted with positional deviation, there will be a case where the two side face portions of adjacent electronic components 101 come into contact with each other as shown in FIG. 16 or a case where an end face portion of one electronic component 101 comes into contact with a side face portion of another electronic component 101 as shown in FIG. 17. In either case, an electrode-electrode short can occur between two electronic components 101.

In order to solve this problem, there is a proposed manufacturing method of electronic component in which the electrodes are formed only on a bottom surface of the electronic component, so as to form no solder fillets or minimize the solder fillets during mounting. (For example, reference is made to Japanese Patent Application Laid-open No. 9-55333 (Japanese Patent No. 3289561) and Japanese Utility Model Laid-open No. S61-65737.)

### SUMMARY OF THE INVENTION

However, the aforementioned electronic component manufacturing method has the problems as described below. It requires high-cost manufacturing equipment for forming the external electrodes on only one limited side face of the electronic component. The internal structure of the electronic component needs to be largely changed from that of the conventional electronic components. Namely, it is necessary to change the structure for leading the internal conductors to the outside. Furthermore, the foregoing method requires a process to damage the product, such as a process of mechanically polishing and removing the formed external electrodes.

Furthermore, since the external electrodes are formed on only one side face of the electronic component, it is difficult to perform an electrical characteristic test after completion of product. These problems can lead to poor productivity of product and increase in product cost.

The present invention has been accomplished in order to solve the above problems and it is an object of the present invention to provide an electronic component of an electrode structure enabling close adjacent high-density mounting of electronic component and a method for manufacturing the electronic component, at low cost.

An aspect of the present invention is a method for manufacturing an electronic component, comprising: a preparation step of preparing an electronic component element, the electronic component element comprising an element body including a pair of end faces opposed to each other, a pair of principal faces extending so as to connect the pair of end faces and opposed to each other, and a pair of side faces extending so as to connect the pair of principal faces and opposed to each other, and an external electrode formed on the end face side of the element body and covering a partial region of the principal face and/or a partial region of the side face adjacent to the end face; a retaining step of adhering one face which is the principal face or the side face of the electronic component element and at least a part of which is covered by the external electrode, to an adhesive retainer, thereby to retain the electronic component element on the adhesive retainer; an application step of collectively applying an insulating resin coating agent onto an exposed surface of the electronic component element retained on the adhesive retainer, by spray coating; a solidification step of solidifying the insulating resin coating agent thus applied, on the adhesive retainer; and a separation step of separating the electronic component element from the adhesive retainer, after the step of solidifying the insulating resin coating agent, whereby the electronic component is manufactured so that an insulating material covers the surface of the element body except for the one face which is the principal face or the side face and at least a part of which is covered by the external electrode, and the external electrode formed on the surface.

Another aspect of the present invention is an electronic component comprising: an element body having a pair of end faces opposed to each other, a pair of principal faces extending so as to connect the pair of end faces and opposed to each other, and a pair of side faces extending so as to connect the pair of principal faces and opposed to each other; an external electrode formed on the end face side of the element body and covering a partial region of the principal face and/or a partial region of the side face adjacent to the end face; and an insulating material covering a surface of the element body except for a face which is the principal face or the side face and at least a part of which is covered by the external electrode, and the external electrode formed on the surface.

The present invention will become more fully understood from the detailed description given hereinbelow and the accompanying drawings which are given by way of illustration only, and thus are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a perspective view illustrating an electronic component according to the first embodiment.

FIG. 2 is a drawing for explaining a sectional configuration of the electronic component according to the first embodiment.

FIG. 3 is a drawing for explaining a sectional configuration of the electronic component according to the first embodiment.

FIG. 4 is a drawing for explaining an insulating resin coating layer forming process.

FIG. 5 is a sectional view illustrating a packaged state of electronic components according to the first embodiment.

FIG. 6 is a perspective view illustrating a mount example of electronic components according to the first embodiment.

FIG. 7 is a plan view illustrating a mount example of electronic components according to the first embodiment.

FIG. 8 is a drawing for explaining a sectional configuration along the line VIII-VIII in FIG. 7.

FIG. 9 is a drawing for explaining a sectional configuration along the line IX-IX in FIG. 7.

FIG. 10 is a plan view illustrating a mount example of electronic components according to the first embodiment.

FIG. 11 is a plan view illustrating a mount example of electronic components according to the first embodiment.

FIG. 12 is a perspective view illustrating a mount example of conventional electronic components.

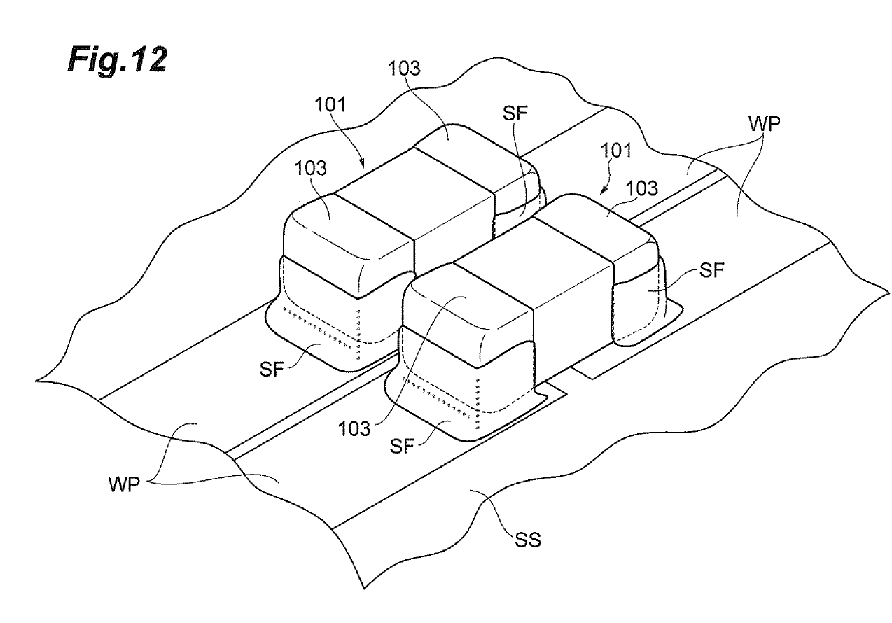

FIG. 13 is a plan view illustrating a mount example of conventional electronic components.

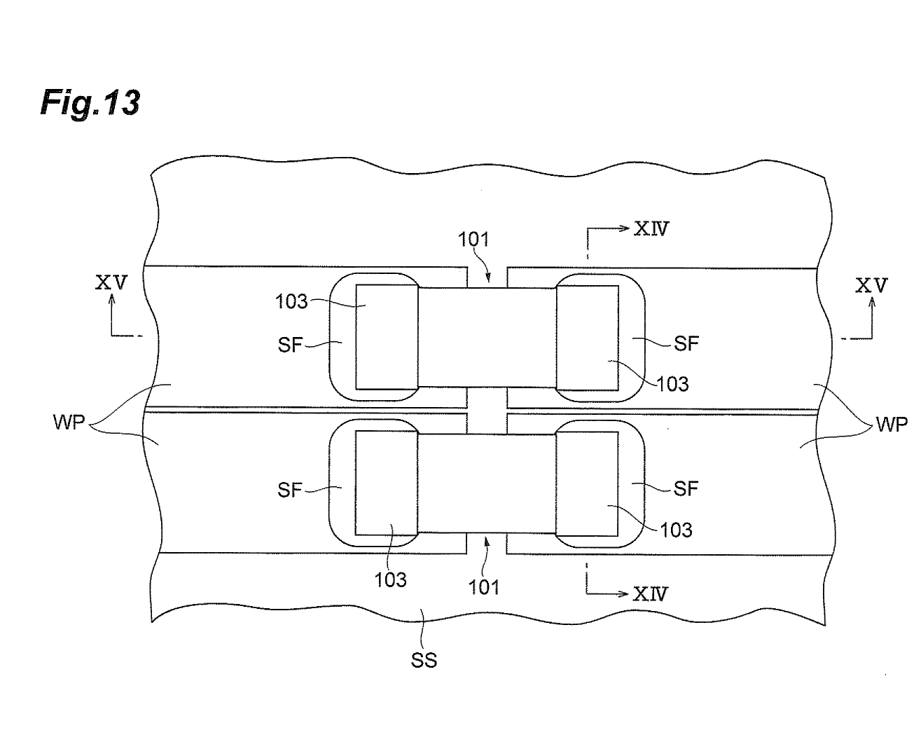

FIG. 14 is a drawing for explaining a sectional configuration along the line XIV-XIV in FIG. 13.

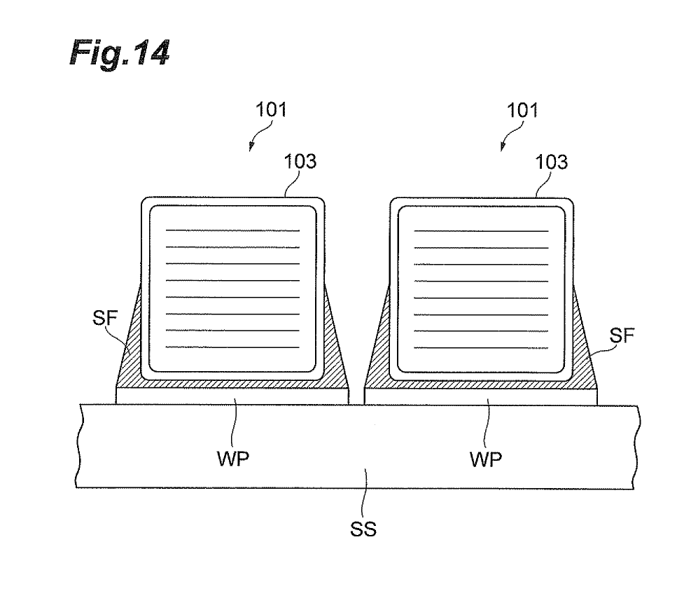

FIG. 15 is a drawing for explaining a sectional configuration along the line XV-XV in FIG. 13.

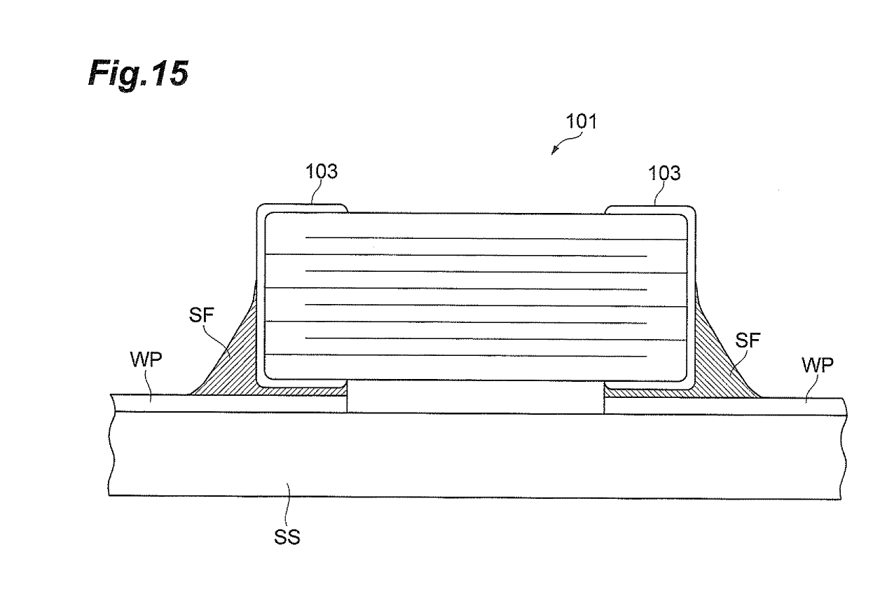

FIG. 16 is a plan view illustrating a mount example of conventional electronic components.

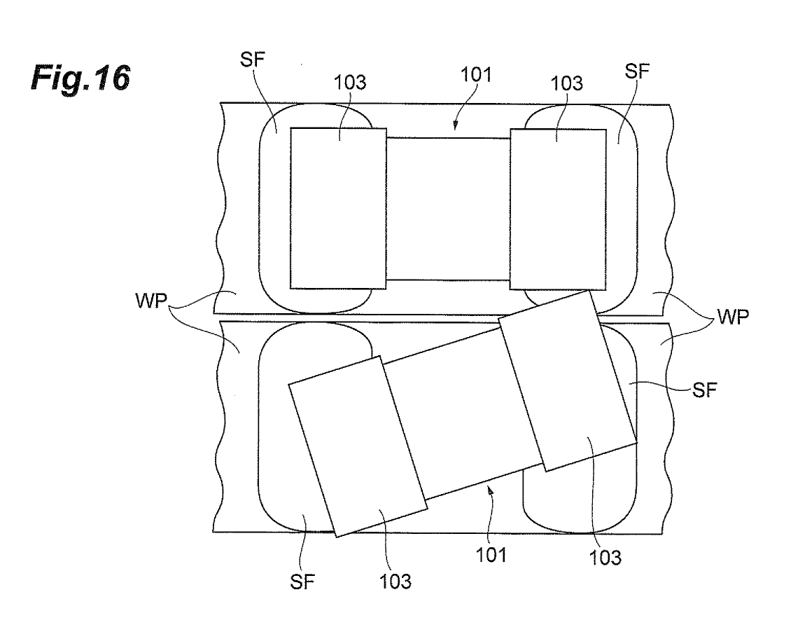

FIG. 17 is a plan view illustrating a mount example of conventional electronic components.

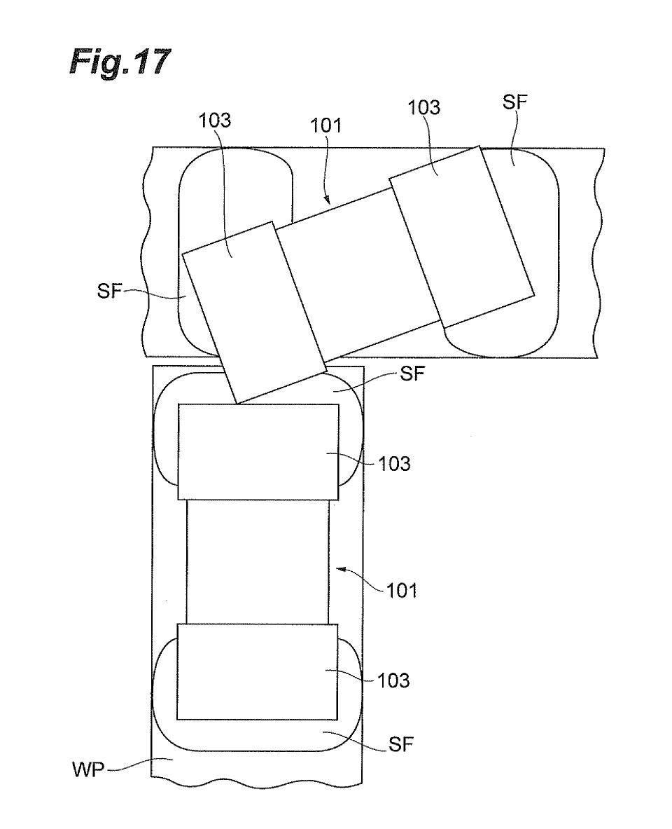

### DESCRIPTION OF THE PREFERRED EMBODIMENTS

The preferred embodiments of the present invention will be described below in detail with reference to the accompanying drawings. In the description, the same elements or elements with the same functionality will be denoted by the same reference signs, without redundant description.

### First Embodiment

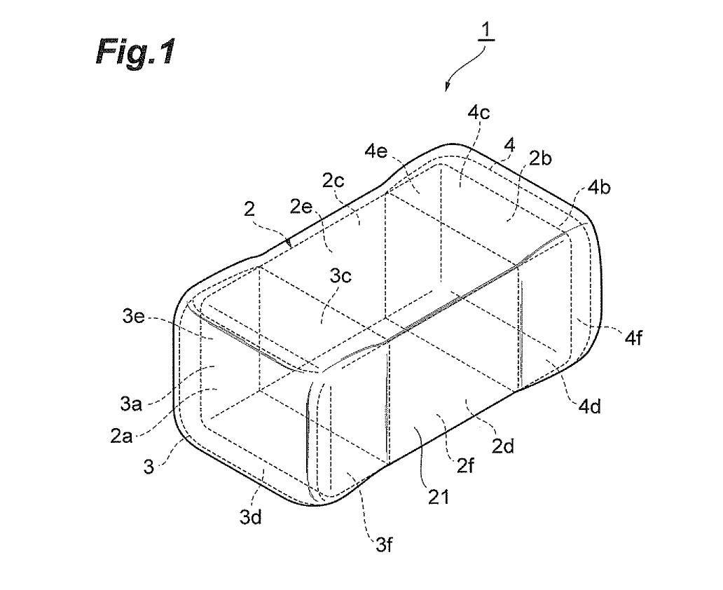

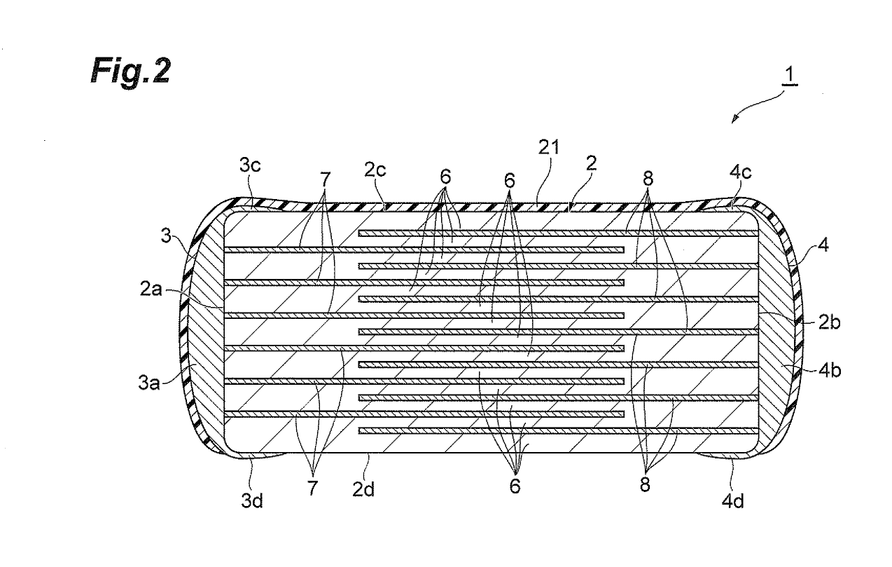

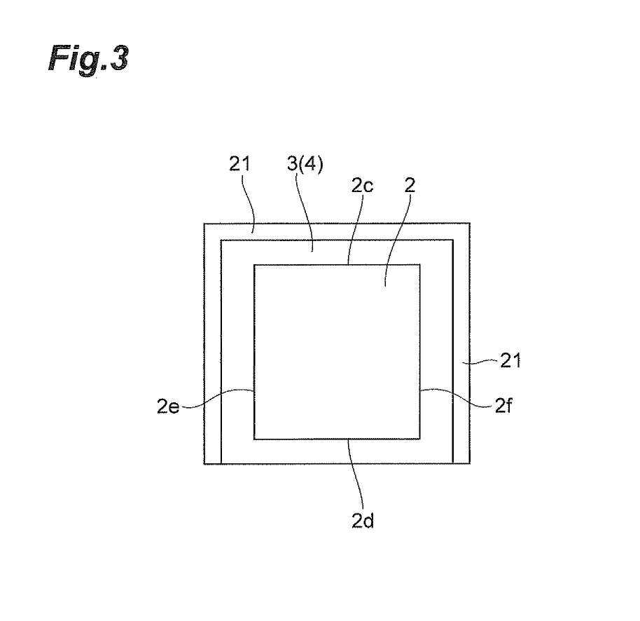

A configuration of an electronic component 1 according to the first embodiment will be described with reference to FIGS. 1 and 2. FIG. 1 is a perspective view illustrating the electronic component of the first embodiment. FIGS. 2 and 3 are drawings for explaining the sectional configuration of the electronic component of the first embodiment. FIG. 3 is drawn without illustration of below-described internal electrodes 7, 8 and others.

The electronic component 1 is, for example, an electronic component such as a multilayer ceramic capacitor. The electronic component 1 is provided with an element body 2 and external electrodes 3, 4. The element body 2 is constructed in a nearly rectangular parallelepiped shape by stacking and integrating a plurality of ceramic green sheets. The element body 2, as also shown in FIG. 1, has a pair of end faces 2a, 2b, a pair of principal faces 2c, 2d, and a pair of side faces 2e, 2f. The pair of end faces 2a, 2b are opposed to each other in the longitudinal direction of the element body 2 and parallel to each other. The pair of principal faces 2c, 2d extend so as to connect the pair of end faces 2a, 2b and are opposed to each other. The pair of side faces 2e, 2f extend so as to connect the pair of principal faces 2c, 2d and are opposed to each other. The external electrodes 3, 4 are formed respectively on the side portions where the two end faces 2a, 2b of the element body 2 are located.

The electronic component 1 is set, for example, in such dimensions as the length of about 0.4 mm to 1.6 mm, the width of about 0.2 mm to 0.8 mm, and the thickness of about 0.4 mm to 0.8 mm.

The element body 2, as shown in FIG. 2, is constructed as a multilayer body in which there are a plurality of rectangular dielectric layers 6 and a plurality of internal electrodes 7 and 8 laminated together. The internal electrodes 7 and the internal electrodes 8 are alternately arranged layer by layer along a lamination direction of the dielectric layers 6 (which will be referred to hereinafter simply as “lamination direction”) in the element body 2. The internal electrodes 7 and the internal electrodes 8 are arranged opposite to each other with at least one dielectric layer 6 in between two internal electrodes 7 and 8.

Each dielectric layer 6 is comprised of a sintered body of a ceramic green sheet, for example, containing a dielectric ceramic (dielectric ceramic such as BaTiO₃, Ba(Ti,Zr)O₃, or (Ba,Ca)TiO₃ type ceramic). In a practical form of the element body 2, the dielectric layers 6 are integrally formed so that no boundary can be visually recognized between the dielectric layers 6.

The internal electrodes 7, 8 contain an electroconductive material, for example, such as Ni or Cu. The thickness of the internal electrodes 7, 8 is, for example, in the range of about 0.5 μm to 3 μm. There are no particular restrictions on the shape of the internal electrodes 7, 8 as long as they are shaped so as to have mutually overlapping regions when viewed from the lamination direction. The internal electrodes 7, 8 have, for example, a rectangular shape. Each of the internal electrodes 7, 8 is constructed as a sintered body of an electroconductive paste containing the aforementioned electroconductive material. The internal electrodes 7 are electrically and physically connected to the external electrode 3, while the internal electrodes 8 are electrically and physically connected to the external electrode 4.

The external electrode 3 is formed so as to cover one end face 2a, partial areas of respective edge regions in the two principal faces 2c, 2d located near the end face 2a, and partial areas of respective edge regions in the two side faces 2e, 2f located near the end face 2a. The external electrode 3 has electrode portions 3a, 3c, 3d, 3e, and 3f lying on the respective corresponding faces 2a, 2c, 2d, 2e, and 2f. The external electrode 3 has the five-face electrode structure.

The external electrode 4 is formed so as to cover the other end face 2b, partial areas of respective edge regions in the two principal faces 2c, 2d located near the end face 2b, and partial areas of respective edge regions in the two side faces 2e, 2f located near the end face 2b. The external electrode 4 has electrode portions 4b, 4c, 4d, 4e, and 4f lying on the respective corresponding faces 2b, 2c, 2d, 2e, and 2f. The external electrode 4 has the five-face electrode structure.

The external electrodes 3, 4 are formed in such a manner that an electroconductive paste is attached to the exterior surface of the element body 2 by a below-described method, it is then sintered at a predetermined temperature (e.g., approximately 700° C.), and plated layers are further formed thereon by electroplating by a below-described method. The electroconductive paste contains, for example, Cu, Ni, Ag, or Pd as a major component. The electroplating can be implemented using Cu, Ni, Sn, or the like.

An insulating layer 21 comprised of an insulating material, as also shown in FIGS. 1 and 3, is formed so as to cover the electrode portions 3c, 3e, 3f, 4c, 4e, and 4f lying on the principal face 2c and side faces 2e, 2f of the element body 2 and the electrode portions 3a, 4b lying on the end faces 2a, 2b. In the present embodiment the insulating layer 21 consists of a below-described insulating resin coating layer.

The below will describe a method for manufacturing the electronic component 1 according to the present embodiment.

(Element Body Preparation Process)

The manufacturing process of electronic component 1 starts from an element body preparation process. The element body preparation process is to form ceramic green sheets for dielectric layers 6, thereafter print patterns for internal electrodes 7, 8 on the ceramic green sheets with an electroconductive paste, and then dry the patterns. This process results in forming the electrode patterns on the ceramic green sheets. The plurality of ceramic green sheets with the electrode patterns thereon are stacked to form a laminate body of the ceramic green sheets. The laminate body of ceramic green sheets is cut to obtain chips each having the size corresponding to the element body 2. Subsequently, water, a plurality of chips, and polishing media are put into a hermetically-closed rotary pot comprised of a material such as polyethylene, and this hermetically-closed rotary pot is rotated to chamfer the corners of the chips. The chips after the chamfering process are thermally treated at a predetermined temperature for a predetermined time to implement debindering thereof. After completion of the debindering, the chips are further fired to obtain element bodies 2.

(External Electrode Forming Process)

An external electrode forming process is carried out as a next process. The external electrode forming process can be performed by making use of a well-known immersion method in an electroconductive paste. This process is carried out using a well-known retainer such as a carrier plate, so that the completed element body 2 is retained on the retainer. Specifically, the retainer retains the principal faces 2e, 2d on the other end face 2b side so that the one end face 2a of the element body 2 faces up.

Next, a first paste layer is formed on the end face 2a side of the element body 2. In this process, first, the end face 2a of the element body 2 retained by the retainer is dipped into an electroconductive paste reserved on an application bed, thereby to apply the electroconductive paste onto the end face 2a side of the element body 2. Thereafter, the electroconductive paste thus applied is dried to form the first paste layer. The electroconductive paste contains Cu, Ni, Ag, or Pd as a major component, as described above. The depth of dip of the element body 2 in the electroconductive paste is properly set so that the first paste layer is formed on the five faces of the respective faces 2a, 2c, 2d, 2e, and 2f. After the first paste layer is dried, a second paste layer is also formed on the five faces of the respective faces 2b, 2c, 2d, 2e, and 2f on the end face 2b side of the element body 2 by the same process. After formation of the first and second paste layers, the element body is thermally treated, for example, at 780° C. to form sintered electrodes.

After formation of the sintered electrodes, a plating process is carried out. The plating process is to form an Ni plated layer and an Sn plated layer on the surfaces of the sintered electrodes. The plating process can be carried out, for example, using a barrel plating system. The element body 2 with the sintered electrodes thereon is immersed in a plating solution in a barrel, and the barrel is then rotated to form a plated layer on the surface of each sintered electrode. The external electrodes 3, 4 each have a composite structure consisting of the sintered electrode and plated layers.

The plated layers have at least an Sn or Sn alloy plated layer as a surface layer, in order to improve wettability of electrode with solder during mounting. If necessary, an Ni or Ni alloy plated layer is formed for preventing reaction of the sintered electrode with solder during mounting, and thereafter the Sn or Sn alloy plated layer is formed. The thickness of the Ni plated layer is from about 0.5 to 6 μm and the thickness of the Sn plated layer from about 1 to 7 μm. Before formation of the Ni plated layer, a Cu plated layer may be formed. If the sintered electrodes are formed by sintering of an Ni paste, the Ni plated layer may be omitted.

An electronic component element (electronic component precursor) 1′ with the element body 2 and external electrodes 3, 4 is prepared through the external electrode forming process. Therefore, the processes from the element body preparation process to the external electrode forming process constitute a component element preparation process.

(Electrical Characteristics and Appearance Inspection Process)

The electronic component element 1′ with the plated layers thereon may be inspected as to its electrical characteristics and appearance at this stage. Since the electronic component element 1′ has the same configuration as surface mount type electronic components of the ordinary five-face electrode structure, measurement facilities having been used heretofore can be used as they are.

(Insulating Resin Coating Layer Forming Process)

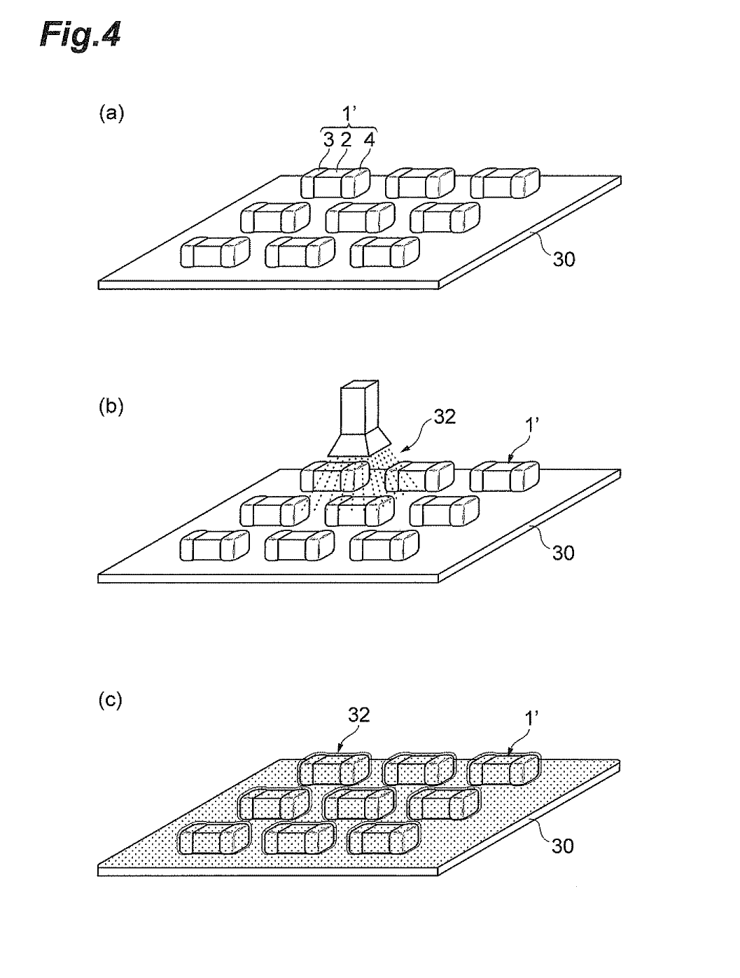

Next, as shown in (a) in FIG. 4, the principal face 2d of each element body 2 (electronic component element 1′) is pressed to an adhesive retainer 30, whereby the electronic component element 1′ is adhesively retained on the adhesive retainer 30 (retaining process). Sections (a) to (c) in FIG. 4 are drawings for explaining an insulating resin coating layer forming process.

The adhesive retainer 30 applicable herein is a so-called adhesive plate. A generally known adhesive plate is, for example, one in which an adhesive layer of an adhesive polymer such as silicone rubber is formed on a metal base plate of stainless steel or the like.

A below-described insulating resin coating layer also remains attached to the adhesive layer, and therefore reuse thereof is difficult. Therefore, it is preferable to use an inexpensive adhesive sheet as the adhesive layer.

The adhesive sheet is more preferably one with heat resistance because an insulating resin coating agent after applied is solidified. Specifically, the adhesive sheet is preferably one obtained by applying silicone rubber or an acrylic adhesive with releasability onto a heat-resistant substrate such as polyethylene, polypropylene, polyvinylidene chloride, polyethylene terephthalate, polyamide, or Japanese paper (washi). For keeping contact faces between the electronic component element 1′ and the adhesive retainer 30 (adhesive layer) in close contact without space, the thickness of the adhesive layer is preferably not less than 10 μm.

The adhesive sheet may be a two-sided adhesive sheet attached to the base plate, or a single-sided adhesive sheet bonded to a metal frame, which is attached to the base plate.

A heat peeling sheet may be used as the adhesive sheet. Use of the heat peeling sheet facilitates separation of the electronic component element 1′, after formation of the insulating resin coating layer.

Next, a liquid insulating resin coating agent 32 is collectively applied onto electronic component elements 1′ adhesively retained on the adhesive retainer 30, by spray coating, as shown in (b) and (c) in FIG. 4 (application process).

The insulating resin coating agent 32 applicable herein is, for example, a thermosetting epoxy resin coating material using a metal oxide pigment, which is used, for example, as a solder resist for printed circuit board. The insulating resin coating agent 32 to be used may be a heat-resistant resin coating material such as a silicone resin coating material, a fluorine resin coating material, a phenolic resin coating material, a urea resin coating material, a melamine resin coating material, an amino resin coating material, an unsaturated polyester resin coating material, a diallyl phthalate resin coating material, a polyurethane resin coating material, a polyimide resin coating material, an alkyd resin coating material, a spirane resin coating material, a thermosetting acrylic resin coating material, a thermosetting methacrylic resin coating material, or a thermosetting copolymer resin coating material, using a metal oxide pigment. A resist material used as a photoresist, e.g., an acrylated epoxy resin or acrylated synthetic rubber, can also be used because it has the thermosetting property.

Preferably, an appropriate amount of an organic pigment or an inorganic pigment is added in these insulating resin coating materials to provide the insulating layer 21 with color or opacity. For example, coloring organic pigments include polycyclic pigments such as phthalocyanine pigments or anthraquinone pigments, or diazo pigments of azo compounds. Coloring inorganic pigments include metal oxides, carbon black, and so on.

A pigment with a large refractive index may be used as the aforementioned metal oxide pigment so as to provide the insulating layer 21 with a moderate light scattering property or substantial opacity.

The spray coating method applicable herein can be a well-known method using a single-fluid or two-fluid mixing nozzle, or an ultrasonic spray nozzle.

Since the contact faces between the electronic component element 1′ and the adhesive retainer 30 are kept in close contact without space by adhesion, the contact faces are not coated with the insulating resin coating agent 32. Namely, the adhesive retainer 30 functions as a retaining means during application of the insulating resin coating agent 32 onto the electronic component element 1′ and also as a mask during application of the insulating resin coating agent 32.

An insulating resin coating layer (insulating layer 21) resulting from solidification of the insulating resin coating agent 32 has the film thickness after solidification, preferably in the range of not less than 2 μm and not more than 30 μm and more preferably in the range of not less than 4 μm and not more than 15 μm. If the insulating resin coating layer is too thin, the insulating resin coating layer will have insufficient mechanical strength in in-plane directions during a process of mounting the electronic component 1 by soldering so as to melt the underlying Sn plated layer; it can result in cracking or delamination of the insulating layer 21, which is not preferred. If the insulating resin coating layer is too thick, the insulating resin coating layer will be subjected to volume contraction during solidification, so as to cause excessive stress; it can result in delamination of the insulating layer 21 during mounting, which is not preferred.

If the film thickness of the insulating resin coating layer is not more than 2 μm, there can be regions not coated with the insulating resin coating layer in portions on the sides of the side faces 2e, 2f of the electronic component element 1′, which is not preferred. When the insulating resin coating layer is not less than 4 μm, it provides sufficient mechanical strength against damage to the insulating layer 21 due to mechanical impact during handling after completion of the electronic component 1 or during mounting thereof with a mounter. If the insulating resin coating layer is not less than 30 μm, a long time will be required for solidification drying and the insulating resin coating layer can have a defect during solidification due to the stress caused by the volume contraction during solidification of the insulating resin coating layer. Furthermore, it is not preferred because the outside dimensions of the electronic component 1 become too large.

The insulating resin coating agent 32 applied onto the faces other than the contact faces by the spray coating method is then subjected to a curing process on the adhesive retainer 30 (solidification process). After the solidification of the insulating resin coating agent 32, the electronic component 1 is separated from the adhesive retainer 30 (separation process).

When the insulating resin coating agent 32 is one of the aforementioned materials, it can be solidified by heating at about 80° C.-160° C. It is sufficient that the solidification of the insulating resin coating agent 32 in this process be fixation of the insulating resin coating agent 32 from a liquid state to a solid state, which may be precure (predrying) at a relatively low temperature.

A preferred process herein is such that the process of applying the insulating resin coating agent 32 and the process of solidifying the insulating resin coating agent 32 on the adhesive retainer 30 are repeated multiple times, provided that the thickness in the liquid state of the insulating resin coating agent 32 per application is small.

By repeating the application and curing of the insulating resin coating agent 32 multiple times, it becomes feasible to reduce a liquid amount of the insulating resin coating agent 32 applied each time in a wet state before curing. If the amount of insulating resin coating agent 32 applied each time is too large, there will appear liquid pools of the insulating resin coating agent 32 due to surface tension, near corners of boundary portions between the adhesive retainer 30 and the electronic component element V. They can cause the insulating resin coating layer on the adhesive retainer 30 to combine with the insulating resin coating layer on the electronic component element 1′, after curing of the insulating resin coating agent 32; it can result in fixing the electronic component element 1′ to the adhesive retainer 30. Even if the electronic component element 1′ can be separated from the adhesive retainer 30, a defect such as a burr can appear in the insulating resin coating layer on the electronic component element 1′ after separated. Therefore, the amount of the insulating resin coating agent 32 applied each time is preferably small.

In the present embodiment, the insulating resin coating agent 32 is collectively applied onto the adhesive retainer 30 and the electronic component elements 1′ adhesively retained on the adhesive retainer 30 and then dried to solidify.

When the electronic component element 1′ is a multilayer ceramic capacitor, the electronic component element 1′ is a composite body of a ceramic material such as BaTiO₃ and an inorganic material (e.g., Ni) forming the internal electrodes, which is mechanically hard and which has a typical coefficient of thermal expansion in the range of about 10 to 12×10⁻⁶/° C. The insulating resin coating agent 32 is an ordinary high-molecular-weight polymer after solidified, depending upon its material, and has the coefficient of thermal expansion at least about 50 to 100 times as large as that of the electronic component element 1′. The adhesive layer part of the adhesive retainer 30 is the silicone rubber or acrylic adhesive, which is mechanically softer than the insulating resin coating layer and which has a larger coefficient of thermal expansion than it.

The insulating resin coating agent 32 in the wet state applied by spin coating is subjected to volume contraction by drying solidification. The electronic component element 1′ is subjected to little thermal expansion or contraction during drying and cooling, when compared to the insulating resin coating layer after solidified. The insulating resin coating agent 32 in the wet state is solidified simply by only the volume contraction in the thickness direction, on the electronic component element 1′ with high mechanical rigidity and the small coefficient of thermal expansion. When cooled, the insulating resin coating agent 32 is subjected to tensile stress in directions parallel to the applied surface.

The insulating resin coating agent 32 applied on the adhesive retainer 30 becomes significantly thermally contracted together with the base during cooling after solidification because the adhesive layer as the base is mechanically soft and has the large coefficient of thermal expansion. Since the boundary portion where the electronic component element 1′ adheres is a mechanically discontinuous portion, large strain and stress are concentrated on that portion. Therefore, if the thickness of the insulating resin coating agent 32 applied and solidified every time is small, the solidified insulating resin coating layer will be broken at the adhering boundary portion by strain during cooling after solidification. This allows the electronic component element 1′ to be separated from the adhesive retainer 30 without production of a burr during separation.

Next, the electronic component element 1′ with the predetermined insulating resin coating layer thereon is mechanically separated from the adhesive retainer 30. A method of the separation, when an ordinary adhesive sheet is used as the adhesive retainer 30, can be a well-known technique with a knife edge or the like. Specifically, after the adhesive sheet is separated from the adhesive retainer 30, the sheet to which the electronic component element 1′ adheres is peeled off while deforming it at an acute angle with the knife edge from the back side.

It is preferable to use the heat peeling sheet for the adhesive retainer 30. When the adhesive retainer 30 is the heat peeling sheet, the electronic component element 1′ can be readily peeled off by heating the adhesive retainer 30.

When the heat peeling sheet is heated, a large number of thermally expandable small balls inside the sheet foam to make the sheet surface so finely uneven as to lose adhesive force. Therefore, the electronic component element 1′ with the insulating resin coating layer thereon can be separated from the adhesive retaining medium by peeling without application of mechanical stress to the electronic component element 1′. This can prevent production of scratches or defects on the insulating resin coating layer during peeling. Since the sheet surface becomes finely uneven due to foaming, great strain is applied to the insulating resin coating layer solidified on the sheet. This makes the insulating resin coating layer more likely to be broken at the boundary portion where the electronic component element 1′ adheres, and thus prevents production of a burr during separation of the electronic component element 1′ from the adhesive retainer 30.

When the solidification of the insulating resin coating agent 32 on the adhesive retainer 30 is precure, a main drying process is carried out as occasion demands. This process results in completely solidifying the insulating resin coating layer.

If there is a burr or the like at end faces of the insulating resin coating layer of the electronic component element 1′, a barrel process by a wet or dry method may be carried out.

In the electronic component 1, the regions except for the principal face 2d of the element body and the electrode portions 3d, 4d formed on the principal face 2d are covered by the insulating resin coating layer (insulating layer 21).

The above-described insulating resin coating layer forming process results in obtaining the electronic component 1 in which the insulating resin coating layer (insulating layer 21) covers the principal face 2c and side faces 2e, 2f, and also covers the electrode portions 3c, 4c, 3e, 4e, 3f, and 4f formed on the principal face 2c and side faces 2e, 2f, and the electrode portions 3a, 4b formed on the end faces 2a, 2b, except for the principal face 2d and the electrode portions 3d, 4d.

(Judgment Process)

Subsequently, a judgment process is carried out to judge the difference of color between the principal face 2d and the faces other than the principal face 2d. Since the faces other than the principal face 2d are coated with the insulating resin coating, there is the difference of color between them. The judgment on this difference of color can be made, for example, with a spectrophotometer. The spectrophotometer measures luminance values L in the CIE (Commission Internationale d'Eclairage) 1976 L*a*b* (CIELAB) (JIS Z8729). When the spectrophotometer is used, it is feasible to mechanically judge the difference of color between the principal face 2d and the faces other than the principal face 2d. This judgment process allows us to easily determine packaging orientation in the next packaging process.

(Packaging Process)

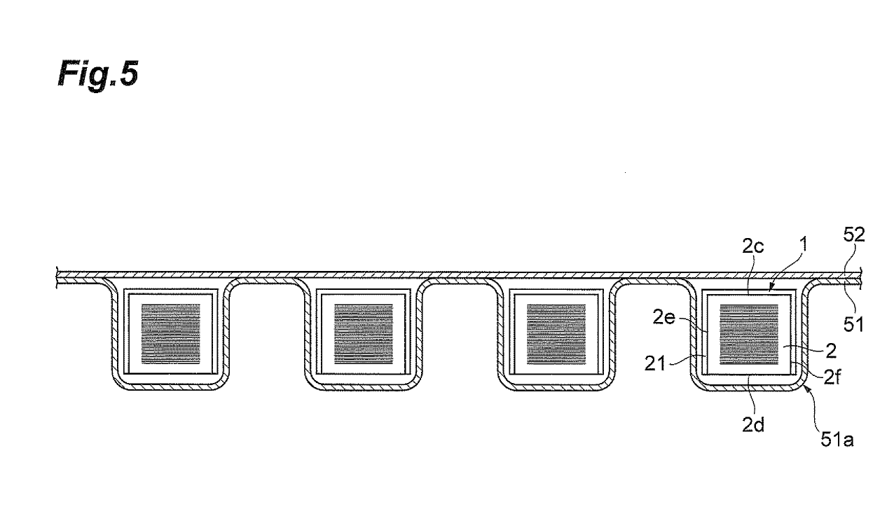

Next, as shown in FIG. 5, the packaging process is carried out to pack the electronic component 1 with the principal face 2c facing an aperture side of a packaging material. The packaging material consists of a packaging material 51 and a packaging material 52. In the packaging material 51, a plurality of recesses 51a of a rectangular section are formed in a two-dimensional array. An electronic component 1 is housed in each of the recesses 51a. The electronic component 1 is housed in the recess 51a so that the principal face 2c faces the aperture side of the packaging material. Thereafter, the apertures of the recesses 51a are covered by the packaging material 52. This completes the packaging process.

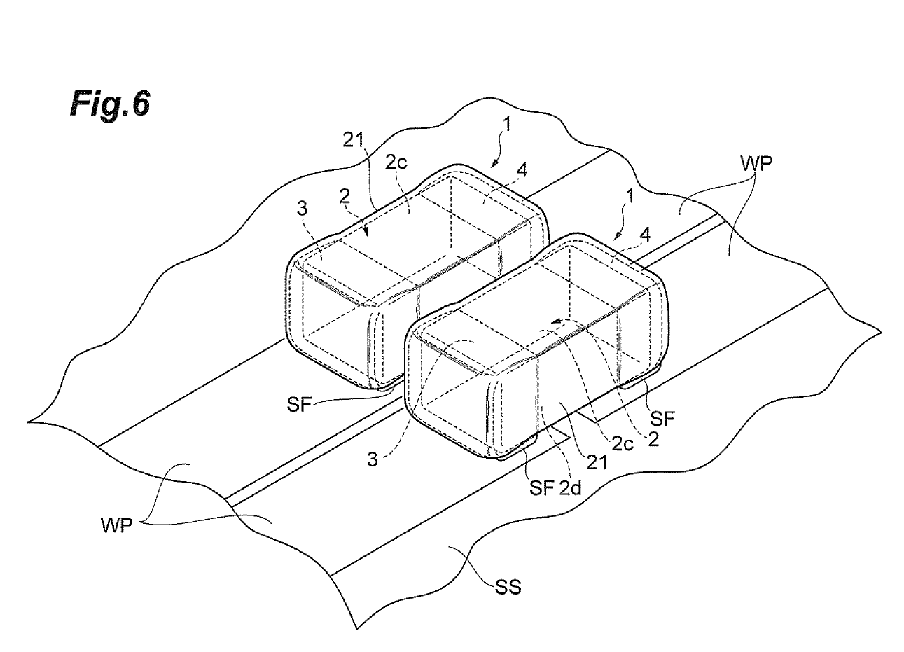

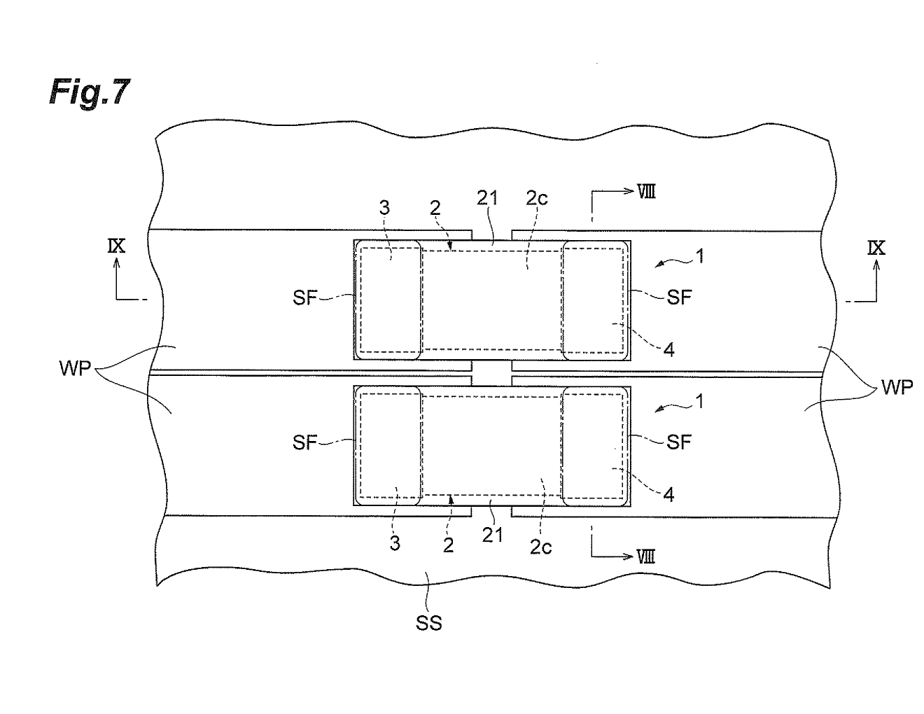

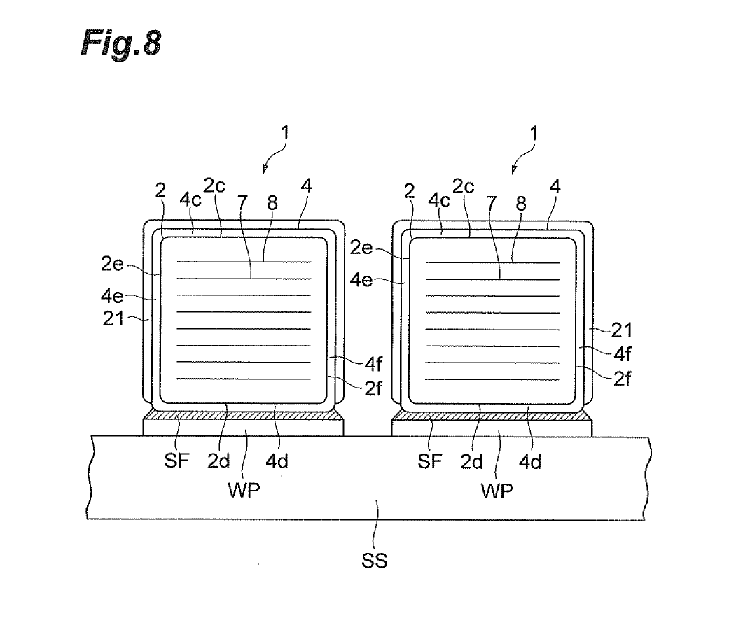

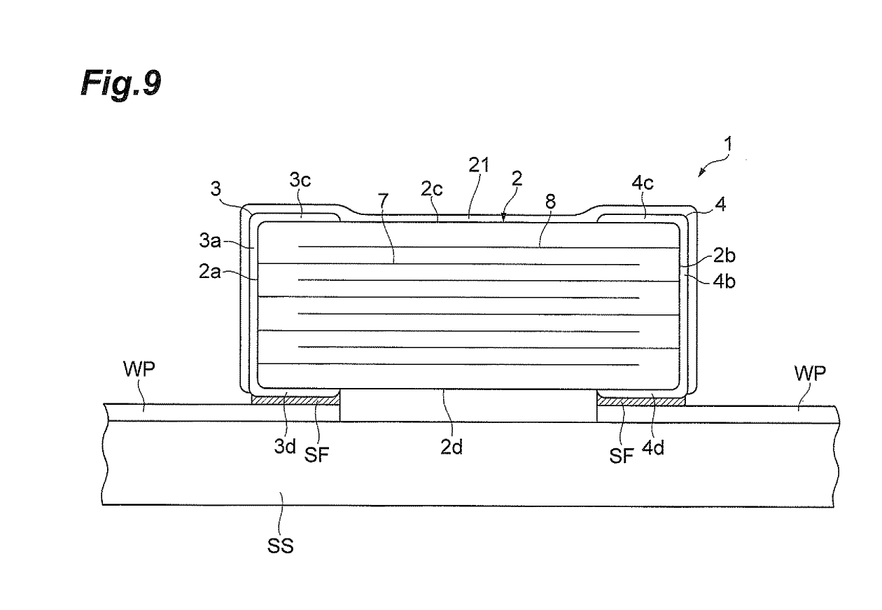

Next, mount examples of the electronic components 1 will be described with reference to FIGS. 6 to 11. FIG. 6 is a perspective view illustrating a mount example of electronic components according to the first embodiment. Each of FIGS. 7, 10, and 11 is a plan view illustrating a mount example of electronic components according to the first embodiment. FIG. 8 is a drawing for explaining a sectional configuration along the line VIII-VIII in FIG. 7. FIG. 9 is a drawing for explaining a sectional configuration along the line IX-IX in FIG. 7. In FIGS. 8 and 9, only below-described solder fillets SF are hatched.

The electronic component 1 is taken out from the packaging material shown in FIG. 5 (packaging material 51 and packaging material 52) and then mounted on a substrate. The electronic component 1 packaged in the packaging material is taken out from the packaging material, using a suction head of a surface-mount mounter. On this occasion, a suction nozzle is in contact with the principal face 2c because in the packaging process the electronic component 1 is packaged in the packaging material with the principal face 2c facing the aperture side of the packaging material. For this reason, the principal face 2d opposed to the principal face 2c is present on the side where a mount surface of a mounting board exists.

On the occasion of mounting the electronic component 1, the external electrodes 3, 4 of the electronic component 1 are electrically connected to respective wiring patterns WP on the substrate SS by solder reflow. Therefore, the electronic component 1 is mounted by soldering, as shown in FIGS. 6 to 9. The solder to be used herein is one of those based on ISO FDIS 9453:2005 (JIS Z 3282:2006), such as Sn—Sb, and the aforementioned insulating resin becomes wet with none of them.

Since no material other than metal becomes wet with the solder, the insulating layer 21 (insulating resin coating layer) functions as a solder resist layer. For this reason, when the electronic component 1 is mounted with the principal face 2d facing the substrate face, the solder does not flow up over the electrode portions 3a, 3c, 3e, 3f, 4b, 4c, 4e, 4f of the electronic component 1, so as to form no solder fillets. This enables close adjacent high-density mounting of electronic components 1.

Accordingly, even if a plurality of electronic components 1 are mounted next to each other with a narrow space, the short problem due to the solder bridge will not occur between adjacent components because there are no solder fillets on the sides of side faces 2e, 2f and on the sides of end faces 2a, 2b as shown in FIGS. 6 to 9.

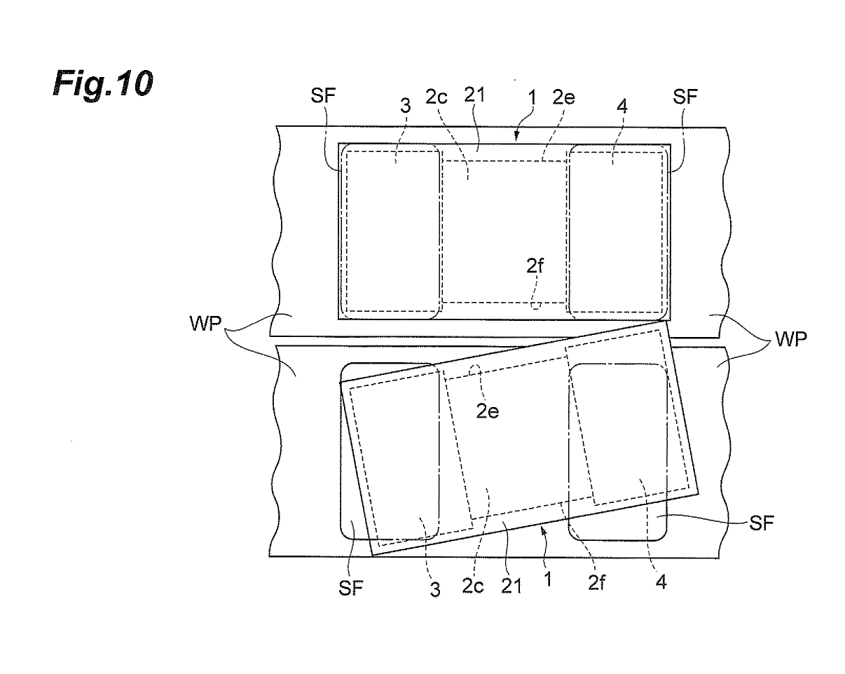

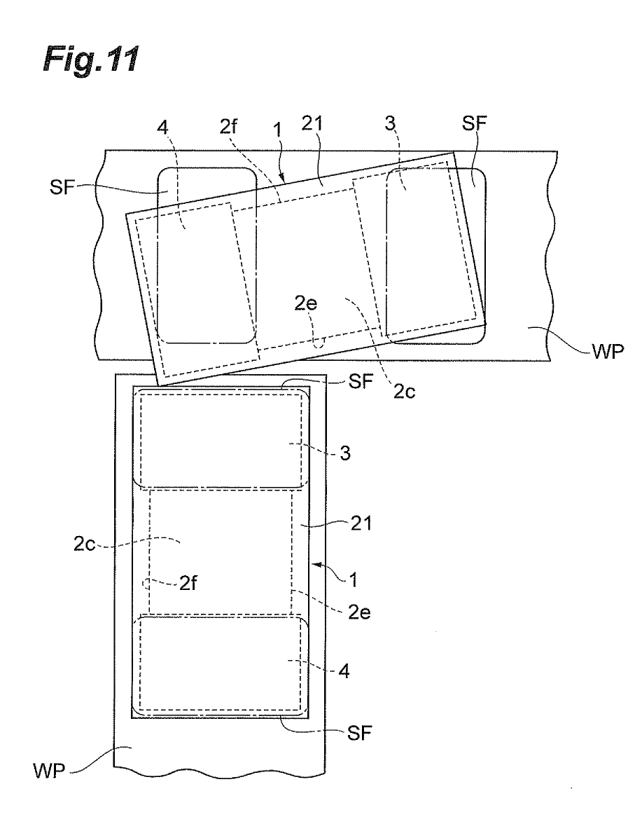

Even if a positional deviation in mounting causes an electronic component 1 to come into contact with a portion on the side face 2e, 2f side or with a portion on the end face 2a, 2b side of an electronic component 1 adjacent thereto, as shown in FIGS. 10 and 11, an electrode-electrode short will not occur between the two electronic components 1 because of the existence of the insulating layer 21 (insulating resin coating layer).

The electronic component 1 of the present embodiment allows the electronic component element 1′ to be manufactured using the same manufacturing processes as ordinary electronic components of the five-face electrode structure. For this reason, there is no need for preparing new manufacturing equipment for manufacturing the electronic component element 1′. Therefore, no equipment investment is needed and the electronic component element 1′ can be prepared at low cost.

In the case of the conventional electronic component where the external electrodes are formed on the bottom face only, the positions of the external electrodes are limited solely to the bottom face. In an electrical characteristic test and screening after completion of a product, therefore, it is necessary to align the product and bring a contact probe into contact therewith, which requires a new test device. For performing the electrical characteristic test with the contact probe being kept accurately in contact with a small electrode portion in an aligned state of a compact product such as a product with the outside shape of 0603 type having the dimensions of 0.6 mm×0.3 mm×0.3 mm or a product with the outside shape of 0402 type having the dimensions of 0.4 mm×0.2 mm×0.2 mm, a lot of time and effort is needed for check of direction, alignment, and high-accuracy positioning of the product. Therefore, it is difficult to perform the test with good productivity.

In the present embodiment, the process of forming the insulating resin coating layer on the electronic component element 1′ is carried out after completion of the sintering process of the sintered electrodes at high temperature and the plating process with great mechanical and electrochemical loads, which significantly affect the electrical characteristics and reliability of the electronic component 1.

For this reason, even if the characteristic test and screening operation of the electronic component element 1′ is carried out before the formation of the insulating resin coating layer, it will not degrade the electrical characteristics and reliability of the product completed finally. Namely, the electrical characteristic test and screening can be carried out using the electrical characteristic test system with good productivity which has been used for the conventional electronic components of the five-face electrode structure. Accordingly, the present embodiment enables the electrical characteristic test with good productivity, without need for new equipment investment for the test system.

In the present embodiment, the insulating resin coating layer is formed after formation of the Sn or Sn alloy plated layer for improvement in wettability of electrodes with the solder, on the sintered electrodes.

For example, in the case where the plated layers are comprised of Sn, the melting point thereof is 231.9° C. Therefore, if the electronic component is mounted at 250° C. which is the peak temperature of a reflow furnace of typical lead-free solder, the plated layers will melt at the peak temperature of the reflow furnace. For this reason, an ordinary inorganic coating film formed on the Sn plated layers can become delaminated or self-destroyed. In the electronic component 1 of the present embodiment, however, the insulating resin coating layer with flexibility is used as the insulating layer 21, and therefore it can absorb strain due to melting of the underlying Sn layers. As a consequence of this, no delamination problem of the insulating layer 21 occurs during reflow in the present embodiment.

Since the insulating layer 21 has flexibility, it is feasible to form the electronic component 1 with high resistance to mechanical impact in handling and with high reliability.

### Second Embodiment

Next, a method for manufacturing the electronic component according to the second embodiment will be described. In the second embodiment, the electronic component element is prepared by the same element body preparation process and external electrode forming process as in the first embodiment.

(Insulating Resin Coating Layer Forming process)

First, the principal face 2d of the element body 2 (electronic component element 1′) is pressed to the adhesive retainer 30, whereby the electronic component element 1′ is adhesively retained on the adhesive retainer 30.

Next, a liquid UV (ultraviolet)-curable insulating resin coating agent is collectively applied onto the electronic component elements 1′ adhesively retained on the adhesive retainer 30, by spray coating.

The UV-curable insulating resin coating agent applicable herein can be, for example, an acrylated epoxy resin coating material using a metal oxide pigment, which is used as a solder resist for printed circuit board. It is also possible to use a coating material used as a heat-resistant coating material, such as an acrylated silicone resin coating material, an acrylated fluorine resin coating material, an acrylated phenolic resin coating material, an acrylated polyurethane resin coating material, an acrylated oil coating material, an acrylated alkyd resin coating material, an acrylated polyester coating material, an acrylated polyether coating material, an acrylated spirane resin coating material, or an acrylated copolymer resin coating material, using a metal oxide pigment. These coating materials may be methacrylated coating materials. It is also possible to use an unsaturated polyester resin coating material or a polyene-polythiol coating material using a metal oxide pigment, which is used as a heat-resistant coating material.

Preferably, an appropriate amount of an organic pigment or an inorganic pigment is added in these heat-resistant resin coating materials so that the insulating layer 21 can have a color or opacity.

Examples of coloring organic pigments include polycyclic pigments of phthalocyanine pigments or anthraquinone pigments, or diazo pigments of azo compounds. Examples of coloring inorganic pigments include metal oxides, carbon black, and so on.

The aforementioned metal oxide pigment may be one with a large refractive index, whereby the insulating layer 21 has a moderate light scattering property, or substantial opacity.

A method of the spray coating applicable herein can be the well-known method as in the first embodiment.

Since the contact faces between the electronic component element 1′ and the adhesive retainer 30 are kept in close contact without space by adhesion, the UV-curable insulating resin coating agent is not applied onto the contact faces. Namely, the adhesive retainer 30 in the present embodiment functions as a retaining means during the application of the UV-curable insulating resin coating agent onto the electronic component element 1′ and also as a mask during the application of the UV-curable insulating resin coating agent.

The UV-curable insulating resin coating layer has the film thickness after solidified, preferably in the range of not less than 2 μm and not more than 30 μm and more preferably in the range of not less than 4 μm and not more than 15 μm. This UV-curable insulating resin coating layer forms the insulating layer 21.

If the UV-curable insulating resin coating layer is too thin, the UV-curable insulating resin coating layer will have insufficient mechanical strength in in-plane directions when the electronic component 1 is mounted by soldering to cause melting of the underlying Sn plated layers; it can result in cracking or delamination of the insulating layer 21, which is not preferred. If the UV-curable insulating resin coating layer is too thick, the stress due to volume contraction will become too high in curing of the insulating resin coating layer; it can result in delamination of the insulating layer 21 during mounting, which is not preferred.

If the film thickness of the UV-curable insulating resin coating layer is not more than 2 μm, regions not coated with the UV-curable insulating resin coating agent can appear in portions on the sides of the side faces 2e, 2f of the electronic component element 1′, which is not preferred.

If the UV-curable insulating resin coating layer is not less than 4 μm, the insulating layer 21 will have sufficient mechanical strength against mechanical impact caused during handling of the electronic component 1 or mounting thereof with a mounter.

If the UV-curable insulating resin coating layer is not less than 30 μm and if the UV-curable insulating resin coating layer has a color, the transmittance for UV light will be poor. For this reason, the time for curing of the insulating resin coating layer with UV light will become long, so as to worsen productivity. Furthermore, the outside dimensions of the electronic component 1 will be too large.

The UV-curable insulating resin coating agent applied onto the faces other than the contact faces by spray coating is then subjected to a UV curing process on the adhesive retainer 30. After the UV-curable insulating resin coating agent is solidified, the electronic component 1 is separated from the adhesive retainer 30.

In the present embodiment, the UV-curable insulating resin coating agent is collectively applied in a state in which the electronic component elements 1′ are adhesively retained on the adhesive retainer 30, and then the UV curing process is carried out. In this process, when UV light is applied from above the adhesive retainer 30, the portions on the sides of the side faces 2e, 2f of the electronic component elements 1′ are located in the shadows and thus cannot be irradiated with a sufficient irradiance of UV light. In order to irradiate the portions on the sides of the side faces 2e, 2f of the electronic component element 1′ with a sufficient irradiance of UV light, a UV source is preferably a planar scattering light source using a diffuse reflector or the like and the light source is located sufficiently in proximity to the adhesive retainer 30.

Although the UV irradiance in the curing depends upon the UV-curable resin to be used, it is preferably at least about three to five times an irradiance in curing of the UV-curable insulating resin coating agent on a planar substrate, in order to achieve sufficient UV irradiation on the portions on the sides of the side faces 2e, 2f of the electronic component element V.

When the coating agent is an acrylic UV-curable insulating resin coating agent, the preferred irradiation is from 200 to 400 mJ/cm² in about 10-20 seconds.

The curing with UV and solidification by heating may be carried out in combination.

In the case of combinational use of UV curing with thermal solidification, a coating agent applicable can be a heat-resistant coating material such as an epoxy resin coating material with a salt of a Lewis acid, an acid-curable amino alkyd resin coating material with an acid generating agent, or a UV-curable insulating resin coating agent mixed with any one of the various resins of the aforementioned thermosetting insulating resin coating agents, using a metal oxide pigment. It is also possible to use an acrylated epoxy resin photoresist or an acrylated synthetic rubber photoresist.

It is preferable to repeat the process of applying the UV-curable insulating resin coating agent and the process of solidifying the applied UV-curable insulating resin coating agent on the adhesive retainer 30, multiple times, provided that the film thickness of the UV-curable insulating resin coating layer per application is set small.

By repeating the application and curing of the UV-curable insulating resin coating agent multiple times, it becomes feasible to reduce a liquid amount of the UV-curable insulating resin coating agent in a wet state before cured, applied each time. If the amount of the UV-curable insulating resin coating agent applied each time is too large, there will appear liquid pools of the insulating resin coating agent due to surface tension, near corners of the boundary portion between the adhesive retainer 30 and the electronic component element 1′. For this reason, after the curing of the UV-curable insulating resin coating agent, the electronic component element 1′ can be fixed to the adhesive retainer 30 because the LW-curable insulating resin coating layer on the adhesive retainer 30 becomes combining with that on the electronic component element 1′. Even if the electronic component element 1′can be separated from the adhesive retainer 30, a defect such as a burr can appear in the UV-curable insulating resin coating layer on the electronic component element 1′ after separated. Therefore, the amount of the UV-curable insulating resin coating agent applied each time is preferably small.

Since the present embodiment employs the UV-curable insulating resin coating agent as the insulating resin coating agent, the curing process time can be reduced to not more than one minute. Therefore, the curing time is considerably reduced in multiple repetitions of application and curing, and the electronic component 1 can be manufactured with good productivity.

In the present embodiment, the curing of the UV-curable insulating resin coating agent after applied can be performed, for example, at a low temperature of not more than 80° C., when compared to the solidification method by thermal drying. For this reason, a UV peeling sheet can be used for the adhesive retainer 30.

The UV peeling sheet significantly decreases its adhesion when irradiated with UV light from the back side of the sheet. For this reason, the electronic component 1 can be readily released in the manufacturing process of the electronic component 1. Since the UV peeling sheet is less expensive than the heat peeling sheet, it is frequently used, particularly, in semiconductor chip manufacturing process.

However, if the UV peeling sheet is exposed to a high temperature, e.g., 80° C. or higher, before the release by UV irradiation, the adhesion reduction action by UV irradiation will be inhibited, so as to result in failure in achieving the release effect.

Since in the present embodiment the applied UV-curable insulating resin coating agent can be cured by UV irradiation at low temperature, the aforementioned adhesion reduction action is not inhibited. Therefore, the low-cost and easily-releasable UV peeling sheet can be used as the adhesive retainer 30.

The UV light is also radiated during curing of the applied UV-curable insulating resin coating agent. An adhesive surface of the UV peeling sheet retaining the electronic component elements 1′ is shielded from the UV irradiation during the curing by the electronic component elements V. Therefore, there will arise no problem of dropping of the electronic component elements 1′ due to degradation of adhesion of the UV peeling sheet retaining the electronic component elements 1′, during the curing of the insulating resin coating agent.

Next, the electronic component element 1′ with the predetermined UV-curable insulating resin coating layer thereon is mechanically separated from the adhesive retainer 30. A method of the separation to be adopted herein may be a well-known technique with a knife edge or the like when an ordinary adhesive sheet is used as the adhesive retainer 30. Specifically, the adhesive sheet is separated from the adhesive retainer 30 and thereafter the sheet with the electronic component element 1′ adhering thereto is peeled off while deforming it at an acute angle with the knife edge from the back side.

When the heat peeling sheet is used as the adhesive retainer 30, the electronic component element 1′ can be readily peeled off by heating the adhesive retainer 30.

When the UV peeling sheet is used as the adhesive retainer 30, the adhesive sheet is separated from the adhesive retainer 30 and thereafter predetermined UV light is applied from the back side of the sheet face to which the electronic component 1 adheres. This decreases the adhesion of the UV peeling sheet, whereby the electronic component element 1′ is peeled off from the UV peeling sheet.

After the separation of the electronic component element 1′, drying solidification at 100° C.-200° C. may be added, if necessary, in order to further enhance the solidification of the UV-curable insulating resin coating layer.

If there is a burr or the like at the end faces of the UV-curable insulating resin coating layer of the electronic component element 1′, the barrel process by wet or dry method may be carried out.

The foregoing insulating resin coating layer forming process can obtain the electronic component 1 in which the UV-curable insulating resin coating layer covers the principal face 2c and side faces 2e, 2f and also covers the electrode portions 3c, 4c, 3e, 4e, 3f, 4f formed on the principal face 2c and side faces 2e, 2f, and the electrode portions 3a, 4b, except for the principal face 2d and electrode portions 3d, 4d.

The resultant electronic component 1 is mounted on a substrate, after having been passed through the same judgment process, packaging process, and mounting process as in the first embodiment.

The above described the preferred embodiments of the present invention, but it should be noted that the present invention is not always limited to the above embodiments and can be modified in many ways without departing from the scope and spirit of the invention.

The first and second embodiments illustrated the examples of the multilayer ceramic capacitor as the electronic component, but the present invention is not limited to it. The present invention can also be applied, for example, to other electronic components such as a multilayer inductor, a multilayer varistor, a multilayer piezoelectric actuator, a multilayer thermistor, or a multilayer composite component.

In the first and second embodiments the electronic component element 1′ has the five-face electrode structure, but the configuration of the electronic component element 1′ does not have to be limited to it. The electronic component element 1′ may have a three-face electrode structure of a so-called C-shape in which the external electrodes are not formed either on the side faces 2e, 2f or on the principal faces 2c, 2d of the element body 2, like chip resistors, or a two-face electrode structure of an L-shape in which the external electrodes are formed on the end faces 2a, 2b and on any one of the side faces 2e, 2f or the principal faces 2c, 2d. The same effects as in the aforementioned embodiments are also achieved in the case where the electronic component element 1′ has the three-face electrode structure or the two-face electrode structure. The same effects as in the aforementioned embodiments are also achieved in the case where the electronic component element 1′ is an electronic component element with multi-terminal external electrodes such as a multilayer capacitor array or a chip type three-terminal feedthrough multilayer capacitor array.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A method for manufacturing an electronic component, comprising:
a preparation step of preparing an electronic component element, said electronic component element comprising an element body including a pair of end faces opposed to each other, a pair of principal faces extending so as to connect the pair of end faces and opposed to each other, and a pair of side faces extending so as to connect the pair of principal faces and opposed to each other, and an external electrode formed on the end face side of the element body and covering a partial region of the principal face and/or a partial region of the side face adjacent to the end face;
a retaining step of adhering one face which is the principal face or the side face of the electronic component element and at least a part of which is covered by the external electrode, to an adhesive retainer, thereby to retain the electronic component element on the adhesive retainer;
an application step of collectively applying an insulating resin coating agent onto an exposed surface of the electronic component element retained on the adhesive retainer, by spray coating;
a solidification step of solidifying the insulating resin coating agent thus applied, on the adhesive retainer; and
a separation step of separating the electronic component element from the adhesive retainer, after the step of solidifying the insulating resin coating agent,
whereby the electronic component is manufactured so that an insulating material covers the surface of the element body except for the one face which is the principal face or the side face and at least a part of which is covered by the external electrode, and the external electrode formed on the surface.

2. The method according to claim 1,
wherein the external electrode has at least a plated layer comprised of Sn or an Sn alloy.

3. The method according to claim 1,
wherein the application step and the solidification step are repeated multiple times.

4. The method according to claim 1,
wherein a heat peeling sheet is used as the adhesive retainer.

5. The method according to claim 1,
wherein the insulating resin coating agent is an ultraviolet-curable insulating resin coating agent.

6. An electronic component comprising:
an element body having a pair of end faces opposed to each other, a pair of principal faces extending so as to connect the pair of end faces and opposed to each other, and a pair of side faces extending so as to connect the pair of principal faces and opposed to each other;
an external electrode formed on the end face side of the element body and covering a partial region of the principal face and/or a partial region of the side face adjacent to the end face; and
an insulating material covering a surface of the element body except for a face which is the principal face or the side face and at least a part of which is covered by the external electrode, and the external electrode formed on the surface.

7. The electronic component according to claim 6,
wherein the external electrode has at least a plated layer comprised of Sn or an Sn alloy, and
wherein the insulating material is an insulating resin coating layer.
